(19) United States
(12) Patent Application Publication
(10) Pub. No.: US 2025/0176231 A1
(43) Pub. Date: May 29, 2025

(54) SEMICONDUCTOR STRUCTURE AND MANUFACTURING METHOD THEREFOR

(71) Applicant: ENKRIS SEMICONDUCTOR, INC., Suzhou (CN)

(72) Inventor: Kai CHENG, Suzhou (CN)

(73) Assignee: ENKRIS SEMICONDUCTOR, INC., Suzhou (CN)

(21) Appl. No.: 18/901,385

(22) Filed: Sep. 30, 2024

(30) Foreign Application Priority Data
Nov. 28, 2023 (CN) 202311605614.8

(51) Int. Cl. H01L 29/06; H01L 29/04; H01L 29/20; H01L 29/66; H01L 29/872

(52) U.S. Cl. CPC H10D 62/103; H10D 8/051; H10D 8/60; H10D 62/117; H10D 62/405; H10D 62/8503

(57) ABSTRACT

Disclose are a semiconductor structure and a manufacturing method therefor. The semiconductor structure includes: a substrate and a multi-channel heterojunction layer stacked in layers, and a P-type epitaxial layer. The multi-channel heterojunction layer includes a plurality of heterojunction layers, and each heterojunction layer includes a channel layer and a barrier layer. The multi-channel heterojunction layer includes a plurality of grooves. The P-type epitaxial layer includes a plurality of first P-type regions filling the plurality of grooves respectively. By forming a transverse PN junction by two-dimensional electron gas in the heterojunction and the first P-type region, a PN junction depletion region is widened in reverse bias to pinch off a current channel, so that the Schottky junction with low barrier height is effectively shielded, reduction effect of the Schottky barrier is suppressed and a reverse leakage current is controlled, thereby increasing breakdown voltage and maintaining a lower turn-on voltage.

### CROSS-REFERENCE TO RELATED APPLICATIONS

The present application claims priority to Chinese Patent Application No. 202311605614.8, filed on Nov. 28, 2023, the content of which is incorporated herein by reference in its entirety.

### TECHNICAL FIELD

The present disclosure relates to the field of semiconductor technologies, and in particular, to a semiconductor structure and a manufacturing method therefor.

### BACKGROUND

Junction Barrier Controlled Schottky Diode (JBS), as an enhancement mode Schottky diode, has become a hot spot of research. The junction barrier controlled Schottky diode not only has characteristics of a Schottky barrier diode including on-state and fast switching, but also has characteristics of a PIN diode including off-state and low leakage current, which are major advantages of the junction barrier controlled Schottky diode. Meanwhile, GaN has significant advantage in preparation of a high-performance power device due to larger bandgap width, higher critical breakdown electric field, and greater saturated electron drift velocity, as well as excellent physical and chemical properties such as chemical stability, high-temperature resistance, and radiation resistance. Therefore, JBS has great application potential.

### SUMMARY

In view of this, embodiments of the present disclosure provide a semiconductor structure and manufacturing method therefor to further reduce reverse leakage current of a GaN-based junction barrier controlled Schottky diode and fully utilize structural advantages of the junction barrier controlled Schottky diode.

According to a first aspect of the present disclosure, a semiconductor structure is provided by an embodiment of the present disclosure. The semiconductor structure includes:
a substrate and a multi-channel heterojunction layer stacked in layers, where the multi-channel heterojunction layer includes a first heterojunction layer, a second heterojunction layer, . . . , an n-th heterojunction layer stacked in sequence in a direction facing away from the substrate, n≥2, each heterojunction layer includes a channel layer and a barrier layer, the multi-channel heterojunction layer includes a plurality of grooves, and a bottom of at least one groove is located in the channel layer of the first heterojunction layer, the plurality of grooves are located at an end of the multi-channel heterojunction layer and arranged at intervals along a first direction, and each groove extends in a second direction perpendicular to the first direction and parallel to a plane where the substrate is located; and a P-type epitaxial layer, including a plurality of first P-type regions filling the plurality of grooves respectively.

According to a second aspect of the present disclosure, a manufacturing method for a semiconductor structure is provided. The method includes the following steps:
providing a substrate, and growing a multi-channel heterojunction layer on the substrate, where the multi-channel heterojunction layer includes a first heterojunction layer, a second heterojunction layer, . . . , an n-th heterojunction layer stacked in sequence in a direction facing away from the substrate, n≥2, each heterojunction layer includes a channel layer and a barrier layer;
performing etching to an end of the multi-channel heterojunction layer to form a plurality of grooves, where a bottom of at least one groove is located in the channel layer of the first heterojunction layer, the plurality of grooves are arranged at intervals along a first direction, and each groove extends in a second direction perpendicular to the first direction and parallel to the plane where the substrate is located; and
performing second epitaxy to form a first P-type region in each of the plurality of grooves.

### BRIEF DESCRIPTION OF THE DRAWINGS

FIG. 1 is a schematic structural diagram of a semiconductor structure according to an embodiment of the present disclosure.

FIG. 2 is a schematic structural diagram of a semiconductor structure according to another embodiment of the present disclosure.

FIG. 3 is a schematic structural diagram of a semiconductor structure according to still another embodiment of the present disclosure.

FIGS. 4a and 4b are front view of a semiconductor structure according to an embodiment of the present disclosure.

FIGS. 5a and 5b are side view of a semiconductor structure according to an embodiment of the present disclosure.

FIG. 6 is a schematic structural diagram of a semiconductor structure according to yet still another embodiment of the present disclosure.

FIGS. 7a and 7b are side view of a semiconductor structure according to an embodiment of the present disclosure.

FIG. 8 is a vertical view of a semiconductor structure according to an embodiment of the present disclosure.

FIG. 9 is a schematic structural diagram of a semiconductor structure according to yet still another embodiment of the present disclosure.

FIG. 10 is a flowchart of a manufacturing method for a semiconductor structure according to an embodiment of the present disclosure.

FIGS. 11 to 14 are schematic intermediate structures of a semiconductor structure during the manufacturing process according to an embodiment of the present disclosure.

### DETAILED DESCRIPTION OF THE EMBODIMENTS

A clear and complete description of technical solutions in embodiments of the present disclosure will be provided with reference to accompanying drawings of the embodiments of the present disclosure in the following. Obviously, the described embodiments are only a part, but not all of the embodiments of the present disclosure. All of the other embodiments that may be obtained by those skilled in the art based on the embodiments in the present disclosure without any inventive effort fall within the protection scope of the present disclosure.

Structural advantages of the junction barrier controlled Schottky diodes cannot be fully utilized by a GaN-based junction barrier controlled Schottky diode due to high leakage caused by dislocation issue of GaN material. In application field of high-voltage switch, how to obtain a GaN diode with lower reverse leakage current, greater reverse withstand voltage, lower forward voltage drop, and simple manufacturing process is still a challenge in related art.

A semiconductor structure and a manufacturing method therefor are provided by the present disclosure to further reduce reverse leakage current of the GaN-based junction barrier controlled Schottky diode and fully utilize the structural advantages of the junction barrier controlled Schottky diode. The semiconductor structure includes a substrate and a multi-channel heterojunction layer stacked in layers, where the multi-channel heterojunction layer includes a plurality of heterojunction layers, each of the heterojunction layer includes a channel layer and a barrier layer, and the multi-channel heterojunction layer includes a plurality of grooves; and a P-type epitaxial layer, including a plurality of first P-type regions filling the plurality of grooves. By forming a transverse PN junction by two-dimensional electron gas in the heterojunction and the first P-type region, a PN junction depletion region is widened in reverse bias to pinch off the current channel, so that the Schottky junction with low barrier height is effectively shielded, reduction effect of the Schottky barrier is suppressed and a reverse leakage current is controlled, thereby increasing breakdown voltage and maintaining a lower turn-on voltage. Meanwhile, by stacking a plurality of heterojunctions in layers, a plurality of paralleled two-dimensional electron gas paths between the anode and cathode may be formed to compensate the depletion of the two-dimensional electron gas by the first P-type region and ensuring forward current of the diode.

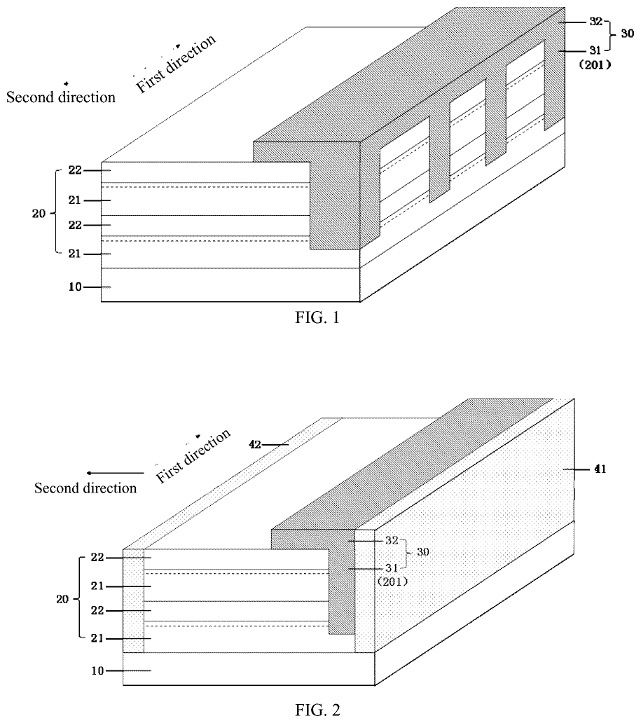

The semiconductor structure and the manufacturing method therefor mentioned in the present disclosure will be described with reference to FIGS. 1 to 14 in the following.

FIG. 1 is a schematic structural diagram of a semiconductor structure according to an embodiment of the present disclosure. FIG. 2 is a schematic structural diagram of a semiconductor structure according to another embodiment of the present disclosure. As shown in FIG. 1, the semiconductor structure includes a substrate 10 and a multi-channel heterojunction layer 20 stacked in layers, and a P-type epitaxial layer 30. The multi-channel heterojunction layer 20 includes a first heterojunction layer, a second heterojunction layer, . . . , an n-th heterojunction layer stacked in sequence in a direction facing away from the substrate 10, where n≥2. Each heterojunction layer includes a channel layer 21 and a barrier layer 22. The multi-channel heterojunction layer 20 includes a plurality of grooves 201, and a bottom of at least one groove 201 is located in the channel layer 21 of the first heterojunction layer. The plurality of grooves 201 are disposed at an end of the multi-channel heterojunction layer 20 and arranged at intervals in sequence along a first direction. Each of the plurality of grooves 201 extends in a second direction perpendicular to the first direction and parallel to a plane where the substrate 10 is located. The P-type epitaxial layer 30 includes a plurality of first P-type regions 31 filling the plurality of grooves 201 respectively. As shown in FIG. 2, the semiconductor structure may further include an anode 41 and a cathode 42, which are located at two ends of the multi-channel heterojunction layer 20. The anode 41 is in contact with the first P-type region 31 and is located at a same end of the multi-channel heterojunction layer 20 as the first P-type region 31.

In this embodiment, the multi-channel heterojunction layer 20 may only include two heterojunction layers, namely, the first and second heterojunction layers stacked in the direction facing away from the substrate 10. In other embodiments, the multi-channel heterojunction layer 20 may include three or more heterojunction layers, namely, the first heterojunction layer, the second heterojunction layer, . . . , the n-th heterojunction layer stacked in sequence in the direction away from the substrate 10, where n≥3. Each heterojunction layer includes a channel layer 21 and a barrier layer 22, and a bandgap width of the material of barrier layer 22 is greater than a bandgap width of material of the channel layer 21. Materials of the channel layer 21 and the barrier layer 22 may include group III nitride material. Two-dimensional electron gas may be formed at the interface between the channel layer 21 and the barrier layer 22. In an optional embodiment, the channel layer 21 is a GaN layer and the barrier layer 22 is an AlGaN layer. In another optional embodiment, the material of the channel layer 21 and the barrier layer 22 may also be GaN/AlN, GaN/InN, GaN/InAlGaN, GaAs/AlGaAs, GaN/InAlN, or InN/InAlN. The material of the plurality of heterojunction layers may be the same or different, which is not limited in the present disclosure.

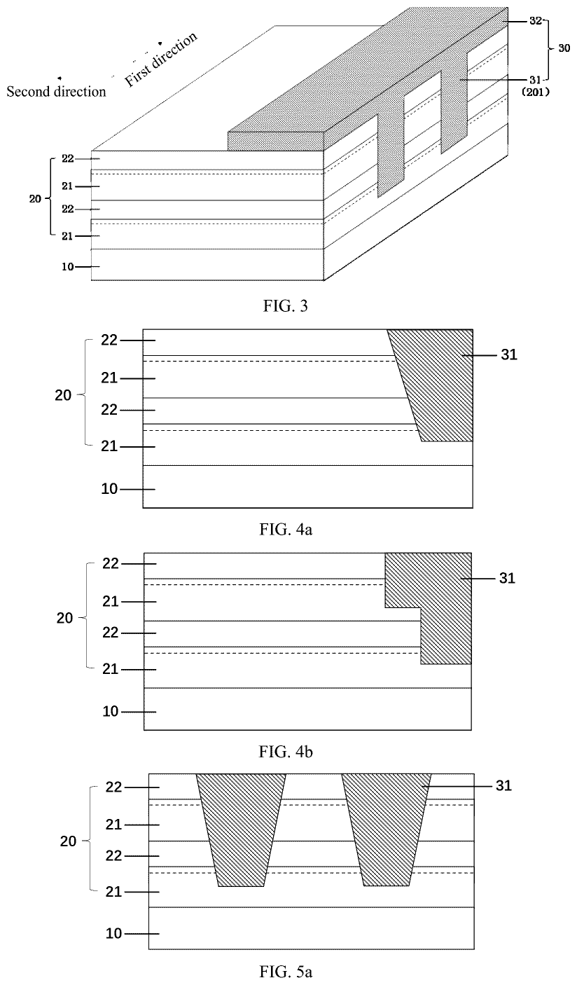

In this embodiment, a bottom surface of the groove 201 in the multi-channel heterojunction layer 20 has (1-100) crystal face or (11-20) crystal face. The groove 201 with (1-100) or (11-20) crystal face on the bottom surface is beneficial for reducing strength of electric field at sharp corners of the groove in subsequent manufactured devices. The groove 201 may also be re-etched to form a rounded corner at the bottom, which may also reduce the electric field strength at the sharp corners of the groove in devices manufactured in subsequent processes. Material of the P-type epitaxial layer 30 filling the groove 201 includes a P-type gallium-nitride-based material. FIG. 3 is a schematic structural diagram of a semiconductor structure according to still another embodiment of the present disclosure. In this embodiment, the groove 201 may be located both inside and at two ends of the multi-channel heterojunction layer 20, as shown in FIG. 1. In another embodiment, the groove 201 may be located only inside the multi-channel heterojunction layer 20, as shown in FIG. 3.

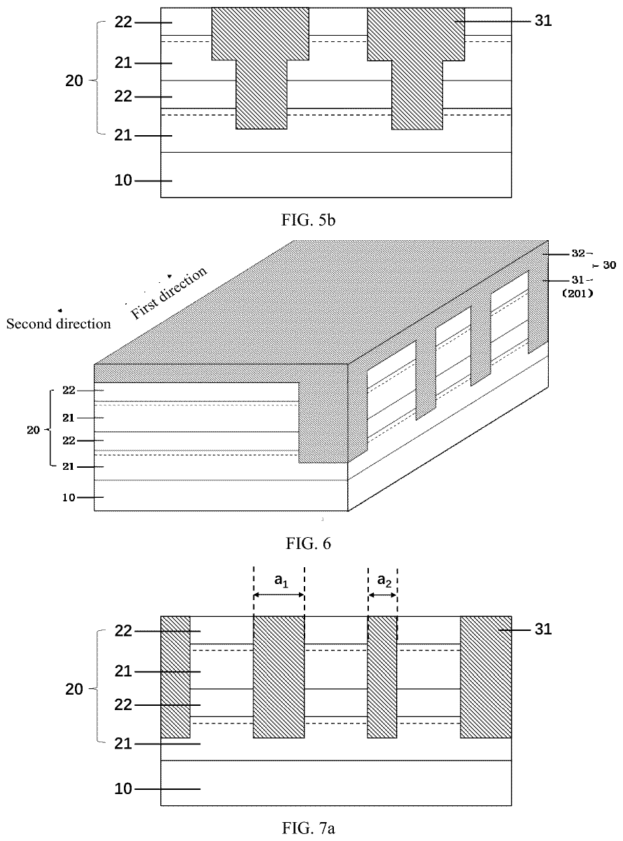

FIG. 4a and FIG. 4b are front view of a semiconductor structure according to an embodiment of the present disclosure. FIG. 5a and FIG. 5b are side view of a semiconductor structure according to an embodiment of the present disclosure. In an embodiment, a contact interface between the channel layer 21 and the barrier layer 22 in each heterojunction layer has two-dimensional electron gas. Lengths of the first P-type region 31, along the second direction and/or along the first direction at different layers of the two-dimensional electron gas are different. Specifically, the length, along the second direction, of each first P-type region 31 uniformly increases (as shown in FIG. 4a) or increases in a stepped mode (as shown in FIG. 4b) in a direction facing away from the substrate 10, and/or, the length, along the first direction, of each first P-type region 31 uniformly increases (as shown in FIG. 5a) or increases in an stepped mode (as shown in FIG. 5b) in the direction facing away from the substrate 10. By changing the lengths of the first P-type region 31 along the second direction and the first direction, on the one hand, a shape of channel may be changed to widen a moving path of electrons, thereby reducing on-state resistance; and on the other hand, a width of a depletion layer may be changed to reduce peak electric field, thereby increasing the breakdown voltage.

FIG. 6 is a schematic structural diagram of a semiconductor structure according to an embodiment of the present disclosure. In an embodiment, as shown in FIG. 1, the P-type epitaxial layer 30 may further include a second P-type layer 32 located on the multi-channel heterojunction layer 20 and the plurality of first P-type regions 31, and the second P-type layer 32 is connected to the plurality of first P-type regions 31 separately. A length, along the second direction, of the second P-type layer 32 is greater than or equal to the length, along the second direction, of the first P-type region 31. Optionally, as shown in FIG. 6, the second P-type layer 32 may fully cover the multi-channel heterojunction layer 20. The first P-type region 31 and the second P-type layer 32 may synergistically redistribute surface electric field of the heterojunction structure between the anode 41 and the cathode 42, thereby improving the electric field distribution at the edge of the anode 41, preventing avalanche breakdown, and further increasing the breakdown voltage and reducing reverse leakage current of the device.

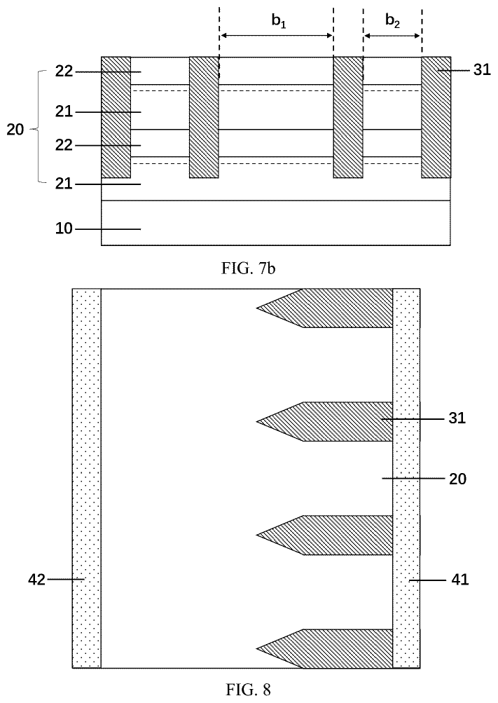

FIG. 7a and FIG. 7b are side view of a semiconductor structure according to an embodiment of the present disclosure. In an embodiment, as shown in FIG. 7a, lengths (a1, a2), along the first direction, of at least two first P-type regions are different. In another embodiment, as shown in FIG. 7b, at least two interval distances (b1, b2), along the first direction, between adjacent first P-type regions are different. By changing the length and interval distance of the plurality of first P-type regions 31 along the first direction, a channel shape and a width of depletion layer may be further changed, and the electron movement path and peak electric field may be adjusted, thereby reducing the on-state resistance and increasing the breakdown voltage.

FIG. 8 is a vertical view of a semiconductor structure according to an embodiment of the present disclosure. In an embodiment, as shown in FIG. 8, an end, closer to the cathode 42 along a direction perpendicular to the substrate, of at least one first P-type region 31 includes a tip. By designing the tip at the end of the first P-type region 31, the electric field distribution between the anode 41 and the cathode 42 may be further improved.

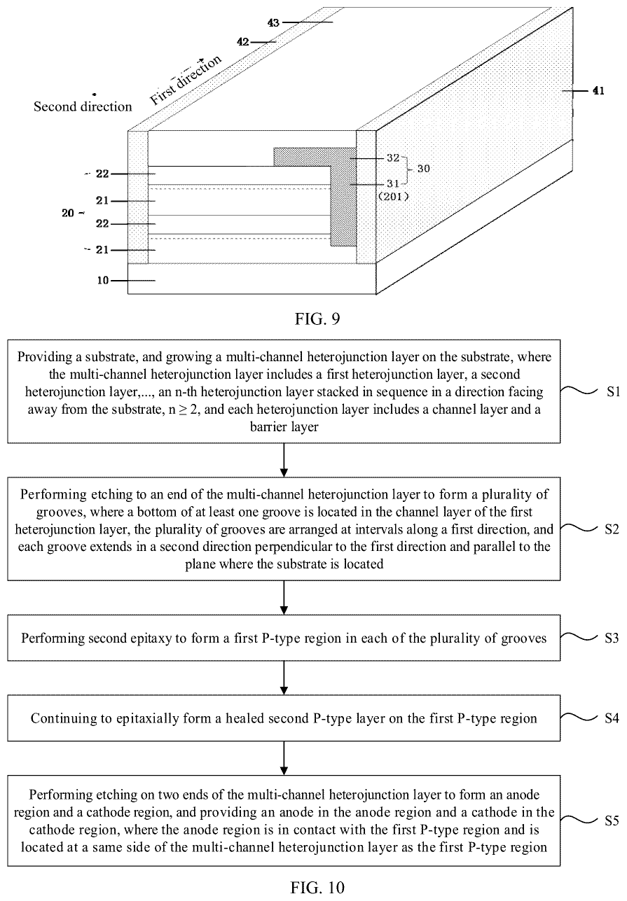

FIG. 9 is a schematic structural diagram of a semiconductor structure according to an embodiment of the present disclosure. In an embodiment, as shown in FIG. 9, the semiconductor structure may further include: a passivation layer 43, fully covering the multi-channel heterojunction layer 20 and the P-type epitaxial layer 30. Material of the passivation layer 43 includes SiN, SiO₂, SiON, Al₂O₃, MgO, Ga₂O₃ or HfO₂. The passivation layer 43 is configured to isolate external water and oxygen from entering the P-type epitaxial layer 30 and the multi-channel heterojunction layer 20.

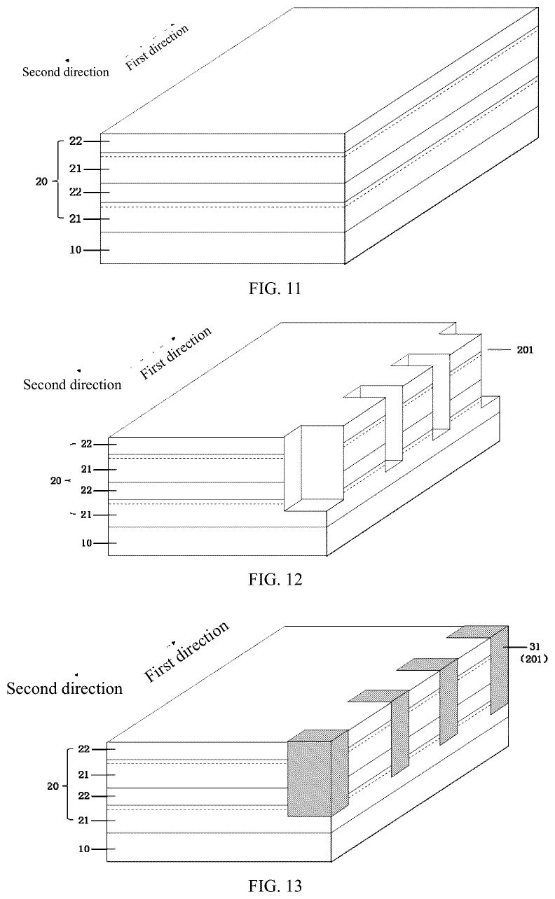

According to another aspect of the present disclosure, FIG. 10 is a flowchart of a manufacturing method for a semiconductor structure according to an embodiment of the present disclosure. FIGS. 11 to 14 are schematic intermediate structures of a semiconductor structure during the manufacturing process according to an embodiment of the present disclosure. As shown in FIG. 10, the manufacturing method for the semiconductor structure provided by an embodiment of the present disclosure includes the following steps.
Step S1: providing a substrate, and growing a multi-channel heterojunction layer on the substrate, where the multi-channel heterojunction layer includes a first heterojunction layer, a second heterojunction layer, . . . , an n-th heterojunction layer stacked in sequence in a direction facing away from the substrate, n≥2, and each heterojunction layer includes a channel layer and a barrier layer.

Specifically, as shown in FIG. 11, the substrate 10 is provided, and the multi-channel heterojunction layer 20 is grown on the substrate 10. The multi-channel heterojunction layer 20 includes a first heterojunction layer, a second heterojunction layer, . . . , an n-th heterojunction layer stacked in sequence in a direction facing away from the substrate 10, n≥2, and each heterojunction layer includes a channel layer 21 and a barrier layer 22. Material of the substrate 10 includes at least one of Si, Al₂O₃, GaN, SiC, and AlN. The method for growing the multi-channel heterojunction layer 20 on the substrate 10 may be in-situ growth, atomic layer deposition (ALD), chemical vapor deposition (CVD), molecular beam epitaxy (MBE), plasma enhanced chemical vapor deposition (PECVD), low pressure chemical vapor deposition (LPCVD), metal-organic chemical vapor deposition (MOCVD), or a combination thereof.
Step S2: performing etching to an end of the multi-channel heterojunction layer to form a plurality of grooves, where a bottom of at least one groove is located in the channel layer of the first heterojunction layer, the plurality of grooves are arranged at intervals along a first direction, and each groove extends in a second direction perpendicular to the first direction and parallel to the plane where the substrate is located.

Specifically, as shown in FIG. 12, the plurality of grooves 201 are etched at an end of the multi-channel heterojunction layer 20. A bottom of at least one groove 201 is located in the channel layer 21 of the first heterojunction layer, and the plurality of grooves 201 are arranged at intervals along the first direction. Each groove 201 extends in a second direction perpendicular to the first direction and parallel to a plane where the substrate 10 is located. By controlling the shape and interval distance of the grooves 201, the shape and interval distance of the first P-shaped regions 31 growing in the grooves 201 may be controlled.
Step S3: performing second epitaxy to form a first P-type region in each of the plurality of grooves.

Specifically, as shown in FIG. 13, the second epitaxy is performed to form the first P-type region 31 in the groove 201. By controlling the shape and interval distance of the first P-shaped region 31 grown in the groove 201, the channel shape and the width of the depletion layer of the semiconductor structure may be adjusted, and the electron movement path and peak electric field may be adjusted, thereby reducing the on-state resistance and increasing the breakdown voltage.
Step S4: continuing to epitaxially form a healed second P-type layer on the first P-type region.

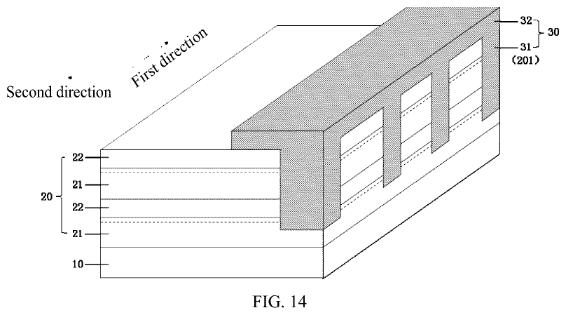

Specifically, as shown in FIG. 14, the epitaxial growth on the first P-type region 31 is continued to form the healed second P-type layer 32. The first P-type region 31 and the second P-type layer 32 may synergistically redistribute the surface electric field of the heterojunction structure between the anode 41 and the cathode 42, thereby improving the electric field distribution at the edge of the anode 41, preventing avalanche breakdown, and further increasing the breakdown voltage and reducing reverse leakage current of the device.
Step S5: performing etching on two ends of the multi-channel heterojunction layer to form an anode region and a cathode region, and providing an anode in the anode region and a cathode in the cathode region, where the anode region is in contact with the first P-type region and is located at a same side of the multi-channel heterojunction layer as the first P-type region.

Specifically, etching process is performed to the two ends of the multi-channel heterojunction layer 20 to form the anode region and the cathode region. The anode region is in contact with the first P-type region 31 and is located at a same side of the multi-channel heterojunction layer 20 as the first P-type region 31. The anode 41 is provided in the anode region and the cathode 42 is provided in the cathode region to form a semiconductor structure as shown in FIG. 2. The junction barrier controlled Schottky diodes prepared with the semiconductor structure provided by the present disclosure may reduce the reverse leakage current of junction barrier controlled Schottky diodes and fully utilize the structural advantages of junction barrier controlled Schottky diodes.

The present disclosure provides a semiconductor structure and a manufacturing method therefor. The semiconductor structure includes: a substrate, a multi-channel heterojunction layer stacked in layers, and a P-type epitaxial layer. The multi-channel heterojunction layer includes a first heterojunction layer, a second heterojunction layer, . . . , an n-th heterojunction layer stacked in sequence in a direction facing away from the substrate, n≥2, and each heterojunction layer includes a channel layer and a barrier layer. The multi-channel heterojunction layer includes a plurality of grooves, and a bottom of at least one groove is located in the channel layer of the first heterojunction layer. The plurality of grooves are located at an end of the multi-channel heterojunction layer and arranged at intervals in sequence along a first direction. Each groove extends in a second direction perpendicular to the first direction and parallel to a plane where the substrate is located. The P-type epitaxial layer includes a plurality of first P-type regions filling the plurality of grooves respectively.

As a transverse PN junction is formed by two-dimensional electron gas in the heterojunction and the first P-type region, the PN junction depletion region is widened in reverse bias to pinch off a current channel, so that the Schottky junction with low barrier height is effectively shielded, reduction effect of the Schottky barrier is suppressed and a reverse leakage current is controlled, thereby increasing breakdown voltage and maintaining a lower turn-on voltage. Meanwhile, by stacking a plurality of heterojunctions in layers, a plurality of paralleled two-dimensional electron gas paths between the anode and cathode may be formed to compensate the depletion of the two-dimensional electron gas by the first P-type region and ensuring forward current of the diode. The first P-type region and the second P-type layer may synergistically redistribute the surface electric field of the heterojunction structure between the anode and the cathode, thereby improving the electric field distribution at the edge of the anode, preventing avalanche breakdown, and further increasing the breakdown voltage and reducing reverse leakage current of the device.

It should be understood that the term “including” and its variations used in the present disclosure are open-ended, that is, “including but not limited to”. The term “one embodiment” means “at least one embodiment”, the term “another embodiment” means “at least one other embodiment”. In this specification, the schematic expressions of the above terms do not necessarily refer to the same embodiments or examples. Moreover, the specific features, structures, materials, or characteristics described can be combined in an appropriate manner in any one or more embodiments or examples. In addition, those skilled in the art may combine and permutation the different embodiments or examples described in this specification, as well as the features of different embodiments or examples, without contradiction.

The above-mentioned embodiments are only the preferred embodiments of the present disclosure, and not intended to limit the protection scope of the present disclosure. Any modification, equivalent replacement, improvement and so on that made in the spirit and principle of the present disclosure shall fall into the protection scope of the present disclosure.

What is claimed is:

1. A semiconductor structure, comprising:
a substrate and a multi-channel heterojunction layer stacked in layers, wherein the multi-channel heterojunction layer comprises a first heterojunction layer, a second heterojunction layer, . . . , an n-th heterojunction layer stacked in sequence in a direction facing away from the substrate, n≥2, each heterojunction layer comprises a channel layer and a barrier layer, the multi-channel heterojunction layer comprises a plurality of grooves, and a bottom of at least one groove is located in the channel layer of the first heterojunction layer, the plurality of grooves are located at an end of the multi-channel heterojunction layer and arranged at intervals along a first direction, and each groove extends in a second direction perpendicular to the first direction and parallel to a plane where the substrate is located; and
a P-type epitaxial layer, comprising a plurality of first P-type regions filling the plurality of grooves respectively.

2. The semiconductor structure according to claim 1, wherein a contact interface between the channel layer and the barrier layer in each heterojunction layer has two-dimensional electron gas, and lengths of the first P-type region, along the second direction and/or along the first direction, in different layers of the two-dimensional electron gas are different.

3. The semiconductor structure according to claim 2, wherein the length, along the second direction, of each first P-type region uniformly increases or increases in a stepped mode in the direction facing away from the substrate.

4. The semiconductor structure according to claim 2, wherein the length, along the first direction, of each first P-type region uniformly increases or increases in a stepped mode in the direction facing away from the substrate.

5. The semiconductor structure according to claim 1, wherein the bottom surface of the groove has (1-100) crystal face or (11-20) crystal face.

6. The semiconductor structure according to claim 1, wherein a bottom surface of the groove experienced secondary etching and has rounded corners.

7. The semiconductor structure according to claim 1, wherein the P-type epitaxial layer further comprises a second P-type layer located on the multi-channel heterojunction layer and the plurality of first P-type regions, and the second P-type layer is connected to the plurality of first P-type regions separately.

8. The semiconductor structure according to claim 7, wherein a length, along the second direction, of the second P-type layer is greater than or equal to a length, along the second direction, of the first P-type region.

9. The semiconductor structure according to claim 8, wherein the second P-type layer fully covers the multi-channel heterojunction layer.

10. The semiconductor structure according to claim 1, wherein lengths, along the first direction, of at least two first P-type regions are different.

11. The semiconductor structure according to claim 1, wherein at least two distances, along the first direction, between adjacent first P-type regions are different.

12. The semiconductor structure according to claim 1, wherein a material of the P-type epitaxial layer comprises a P-type gallium-nitride-based material.

13. The semiconductor structure according to claim 1, further comprising:
an anode and a cathode, located at two ends of the multi-channel heterojunction layer,
wherein the anode is in contact with the first P-type region and is located at a same end of the multi-channel heterojunction layer as the first P-type region.

14. The semiconductor structure according to claim 13, wherein an end, closer to the cathode, of at least one first P-type region comprises a tip.

15. The semiconductor structure according to claim 1, further comprising:
a passivation layer, fully covering the multi-channel heterojunction layer and the P-type epitaxial layer.

16. The semiconductor structure according to claim 15, wherein a material of the passivation layer comprises SiN, SiO₂, SiON, Al₂O₃, MgO, Ga₂O₃ or HfO₂.

17. A manufacturing method for a semiconductor structure, comprising:
providing a substrate, and growing a multi-channel heterojunction layer on the substrate, wherein the multi-channel heterojunction layer comprises a first heterojunction layer, a second heterojunction layer, . . . , an n-th heterojunction layer stacked in sequence in a direction facing away from the substrate, n≥2, each heterojunction layer comprises a channel layer and a barrier layer;
performing etching to an end of the multi-channel heterojunction layer to form a plurality of grooves, wherein a bottom of at least one groove is located in the channel layer of the first heterojunction layer, the plurality of grooves are arranged at intervals along a first direction, and each groove extends in a second direction perpendicular to the first direction and parallel to the plane where the substrate is located; and
performing second epitaxy to form a first P-type region in each of the plurality of grooves.

18. The manufacturing method for the semiconductor structure according to claim 17, further comprising:
continuing to epitaxially form a healed second P-type layer on the first P-type region.

19. The manufacturing method for the semiconductor structure according to claim 17, further comprising:
performing etching to two ends of the multi-channel heterojunction layer to form an anode region and a cathode region, and providing an anode in the anode region and a cathode in the cathode region, wherein the anode region is in contact with the first P-type region and is located at a same side of the multi-channel heterojunction layer as the first P-type region.
